(19) United States
(12) Patent Application Publication
(10) Pub. No.: US 2024/0347617 A1
(43) Pub. Date: Oct. 17, 2024

(54) ELEMENTAL DOPING OF HIGH-K DIELECTRIC OXIDE TO CREATE P-TYPE CONDUCTIVITY IN THIN LAYER CHANNELS VIA SURFACE CHARGE TRANSFER

(71) Applicant: SAMSUNG ELECTRONICS CO., LTD., Suwon-si (KR)

(72) Inventors: Nikhil Sivadas, Boston, MA (US); Yongwoo Shin, Concord, MA (US); Mahdi Amachraa, Cambridge, MA (US)

(73) Assignee: SAMSUNG ELECTRONICS CO., LTD., Suwon-si (KR)

(21) Appl. No.: 18/232,549

(22) Filed: Aug. 10, 2023

Related U.S. Application Data
(60) Provisional application No. 63/466,793, filed on May 16, 2023.
(60) Provisional application No. 63/496,018, filed on Apr. 13, 2023.

(51) Int. Cl. H01L 29/51; H01L 29/49

(52) U.S. Cl. CPC H01L 29/517; H01L 29/4966

(57) ABSTRACT

A structure includes a p-doped thin layer and an oxide high-k gate dielectric layer doped with Cd, As, Cr, Pd, Sc, V, Sn, Mo, Mn, Ti, Ge, Ag, Ni, In, or Ga within a fractional (x) limit 0<x<0.25, wherein the thin layer has a thickness of 10 nm or less, and another structure includes a p-doped transition metal dichalcogenide layer with a binary oxide high-k gate dielectric layer doped with V, Sn, Mo, Mn, Ti, Ge, Ag, Ni, In, or Ga within a fractional (x) limit 0<x<0.2. A method for p-doping a thin layer includes doping an oxide high-k gate dielectric layer with Cd, As, Cr, Pd, Sc, V, Sn, Mo, Mn, Ti, Ge, Ag, Ni, In, or Ga within a fractional (x) limit 0<x<0.25 to thereby p-dope the thin layer by surface charge transfer doping, wherein the thin layer has a thickness of 10 nm or less.

### CROSS-REFERENCE TO RELATED APPLICATIONS

This application is based on and claims priority from U.S. Provisional Application No. 63/496,018 filed on Apr. 13, 2023 and U.S. Provisional Application No. 63/466,793 filed on May 16, 2023 in the U.S. Patent and Trademark Office, the disclosures of which are incorporated herein by reference in their entirety.

### BACKGROUND

### 1. Field

The subject matter disclosed herein relates to structures including substitution doped high-k dielectric materials used to induce p-type doping in thin layer channels via surface charge transfer, and it also relates to methods which include doping an oxide high-k gate dielectric layer to thereby p-dope a thin layer by surface charge transfer doping. The subject matter disclosed herein also relates to structures including doped high-k dielectric materials used to form p-type transition metal dichalcogenide channels via surface charge transfer, and it also relates to methods which include doping a binary oxide high-k gate dielectric layer to thereby p-dope a transition metal dichalcogenide layer by surface charge transfer doping.

### 2. Description of the Related Art

The use of high-k dielectrics is crucial for reducing the effective oxide thickness in transistors, which in turn allows for smaller and faster device performance. In this regard, the metronomic progress in CMOS transistor density and switching energy over time is shown in FIG. 1.

The performance of Si-based transistors degrades significantly as the channel thickness is reduced below 4 nm. This limits the application of Si-based transistors for making next-generation transistors that are atomically thin and thereby are faster and more energy efficient.

To make a transistor such as the one shown in FIG. 2 smaller, one approach is geometry scaling, which makes everything in the transistor smaller. Another approach is equivalent scaling, which uses other oxides instead of SiO₂, where those other oxides have a lower equivalent oxide thickness (EOT) than SiO₂ (that is, oxides which, when used in a smaller layer thickness than SiO₂, can give the same device metrics as with SiO₂). In particular, by using high-k materials (e.g., HfO₂), EOT can be lowered.

Compared to Si-based transistors (SOI in FIG. 3), transition metal dichalcogenide (TMD)-based semiconducting van der Waal's materials (MX₂, M=Mo, W; X=S, Se) show robust mobility for channels having an atomically thin layer thickness. Further, as they have a layered structure and the different layers are held together with weak forces, these materials are stable in the monolayer limit with no dangling bonds that can degrade device performance.

However, strategies to p-dope TMDs have been largely unsuccessful, and a new strategy is desired.

### SUMMARY

An object of the disclosure is to provide a new strategy to p-dope thin layers, and another object of the disclosure is to provide a new strategy to p-dope transition metal dichalcogenides.

To meet these objects, the disclosure provides a strategy for p-doping a thin layer comprising doping an oxide high-k gate dielectric layer with Cd, As, Cr, Pd, Sc, V, Sn, Mo, Mn, Ti, Ge, Ag, Ni, In, or Ga within a fractional (x) limit 0<x<0.25 to thereby p-dope the thin layer by surface charge transfer doping, and the disclosure also provides a strategy for p-doping a transition metal dichalcogenide layer comprising doping a binary oxide high-k gate dielectric layer with V, Sn, Mo, Mn, Ti, Ge, Ag, Ni, In, or Ga within a fractional (x) limit 0<x<0.2 to thereby p-dope the transition metal dichalcogenide layer by surface charge transfer doping.

As a result, the disclosure includes a list of chemistries to p-dope thin layers using oxide high-k gate dielectric (e.g., HfO₂) by doping the oxide layer with Cd, As, Cr, Pd, Sc, V, Sn, Mo, Mn, Ti, Ge, Ag, Ni, In, or Ga within the fractional (x) limit 0<x<0.25, and the disclosure also includes a list of chemistries to p-dope transition metal dichalcogenides (TMDs) using binary oxide high-k gate dielectric (e.g., HfO₂) by doping the oxide layer with Cr, V, Sn, Mo, Mn, Ti, Ge, Ag, Ni, In, or Ga within the fractional (x) limit 0<x<0.2.

The disclosure also includes a method to p-dope a thin layer using oxide high-k gate dielectric (e.g., HfO₂) by doping the oxide layer with Cd, As, Cr, Pd, Sc, V, Sn, Mo, Mn, Ti, Ge, Ag, Ni, In, or Ga within the fractional (x) limit 0<x<0.25 to thereby p-dope the thin layer by surface charge transfer doping, and the disclosure also includes a method to p-dope a TMD using binary oxide high-k gate dielectric (e.g., HfO₂) by doping the oxide layer with V, Sn, Mo, Mn, Ti, Ge, Ag, Ni, In, or Ga within the fractional (x) limit 0<x<0.2 to thereby p-dope the TMD by surface charge transfer doping.

Thus, the disclosure includes the following embodiments.

Embodiment 1: A structure comprising a p-doped thin layer and an oxide high-k gate dielectric layer doped with Cd, As, Cr, Pd, Sc, V, Sn, Mo, Mn, Ti, Ge, Ag, Ni, In, or Ga within a fractional (x) limit 0<x<0.25, wherein the thin layer has a thickness of 10 nm or less.

Embodiment 2: A structure comprising a p-doped transition metal dichalcogenide layer and a binary oxide high-k gate dielectric layer doped with Cr, V, Sn, Mo, Mn, Ti, Ge, Ag, Ni, In, or Ga within a fractional (x) limit 0<x<0.2.

Embodiment 3: The structure according to Embodiment 1, wherein the thin layer is a transition metal dichalcogenide layer.

Embodiment 4: The structure according to Embodiment 3, wherein the transition metal dichalcogenide layer comprises a transition metal dichalcogenide selected from MoS₂, MoSe₂, WS₂, and WSe₂.

Embodiment 5: The structure according to Embodiment 4, wherein the transition metal dichalcogenide is selected from MoS₂ and WSe₂.

Embodiment 6: The structure according to Embodiment 1, wherein the oxide high-k gate dielectric layer comprises HfO₂, ZrO₂, BaTiO₃, or doped-SrTiO₃.

Embodiment 7: The structure according to Embodiment 6, wherein the oxide high-k gate dielectric layer comprises HfO₂.

Embodiment 8: The structure according to Embodiment 1, wherein the oxide high-k gate dielectric layer is doped with Sn, Mo, Ti, Ge, or Ni.

Embodiment 9: The structure according to Embodiment 8, wherein the oxide high-k gate dielectric layer is doped with Ni.

Embodiment 10: The structure according to Embodiment 2, wherein the p-doped transition metal dichalcogenide layer comprises a transition metal dichalcogenide selected from MoS₂ and WSe₂, the oxide high-k gate dielectric layer comprises HfO₂, and the oxide high-k gate dielectric layer is doped with Ni.

Embodiment 11: A method for p-doping a thin layer comprising doping an oxide high-k gate dielectric layer with Cd, As, Cr, Pd, Sc, V, Sn, Mo, Mn, Ti, Ge, Ag, Ni, In, or Ga within a fractional (x) limit 0<x<0.25 to thereby p-dope the thin layer by surface charge transfer doping and form a structure according to Embodiment 1, wherein the thin layer has a thickness of 10 nm or less.

Embodiment 12: A method for p-doping a transition metal dichalcogenide layer comprising doping a binary oxide high-k gate dielectric layer with V, Sn, Mo, Mn, Ti, Ge, Ag, Ni, In, or Ga within a fractional (x) limit 0<x<0.2 to thereby p-dope the transition metal dichalcogenide layer by surface charge transfer doping and form a structure according to Embodiment 2.

Embodiment 13: The method according to Embodiment 11, wherein the thin layer is a transition metal dichalcogenide layer.

Embodiment 14: The method according to Embodiment 13, wherein the transition metal dichalcogenide layer comprises a transition metal dichalcogenide selected from MoS₂, MoSe₂, WS₂, and WSe₂.

Embodiment 15: The method according to Embodiment 14, wherein the transition metal dichalcogenide is selected from MoS₂ and WSe₂.

Embodiment 16: The method according to Embodiment 11, wherein the oxide high-k gate dielectric layer comprises HfO₂, ZrO₂, BaTiO₃, or doped-SrTiO₃.

Embodiment 17: The method according to Embodiment 16, wherein the oxide high-k gate dielectric layer comprises HfO₂.

Embodiment 18: The method according to Embodiment 11, wherein the oxide high-k gate dielectric layer is doped with Sn, Mo, Ti, Ge, or Ni.

Embodiment 19: The method according to Embodiment 18, wherein the oxide high-k gate dielectric layer is doped with Ni.

Embodiment 20: The method according to Embodiment 12, wherein the p-doped transition metal dichalcogenide layer comprises a transition metal dichalcogenide selected from MoS₂ and WSe₂, the oxide high-k gate dielectric layer comprises HfO₂, and the oxide high-k gate dielectric layer is doped with Ni.

Embodiment 21: A structure comprising a p-doped transition metal dichalcogenide layer with a binary oxide high-k gate dielectric layer doped with V, Sn, Mo, Mn, Ti, Ge, Ag, Ni, In, or Ga within a fractional (x) limit 0<x<0.2.

Embodiment 22: The structure according to Embodiment 21, wherein the transition metal dichalcogenide is MoS₂.

Embodiment 23: The structure according to Embodiment 21, wherein the transition metal dichalcogenide is MoSe₂.

Embodiment 24: The structure according to Embodiment 21, wherein the transition metal dichalcogenide is WS₂.

Embodiment 25: The structure according to Embodiment 21, wherein the transition metal dichalcogenide is WSe₂.

Embodiment 26: The structure according to Embodiment 21, wherein the binary oxide high-k gate dielectric is HfO₂.

Embodiment 27: The structure according to Embodiment 22, wherein the binary oxide high-k gate dielectric is HfO₂.

Embodiment 28: The structure according to Embodiment 25, wherein the binary oxide high-k gate dielectric is HfO₂.

Embodiment 29: The structure according to Embodiment 27, wherein the binary oxide high-k gate dielectric layer is doped with Ni.

Embodiment 30: The structure according to Embodiment 28, wherein the binary oxide high-k gate dielectric layer is doped with Ni.

Embodiment 31: A method for p-doping a transition metal dichalcogenide layer comprising doping a binary oxide high-k gate dielectric layer with V, Sn, Mo, Mn, Ti, Ge, Ag, Ni, In, or Ga within a fractional (x) limit 0<x<0.2 to thereby p-dope the transition metal dichalcogenide layer by surface charge transfer doping.

Embodiment 32: The method according to Embodiment 31, wherein the transition metal dichalcogenide is MoS₂.

Embodiment 33: The method according to Embodiment 31, wherein the transition metal dichalcogenide is MoSe₂.

Embodiment 34: The method according to Embodiment 31, wherein the transition metal dichalcogenide is WS₂.

Embodiment 35: The method according to Embodiment 31, wherein the transition metal dichalcogenide is WSe₂.

Embodiment 36: The method according to Embodiment 31, wherein the binary oxide high-k gate dielectric is HfO₂.

Embodiment 37: The method according to Embodiment 32, wherein the binary oxide high-k gate dielectric is HfO₂.

Embodiment 38: The method according to Embodiment 35, wherein the binary oxide high-k gate dielectric is HfO₂.

Embodiment 39: The method according to Embodiment 37, wherein the binary oxide high-k gate dielectric layer is doped with Ni.

Embodiment 40: The method according to Embodiment 38, wherein the binary oxide high-k gate dielectric layer is doped with Ni.

### BRIEF DESCRIPTION OF DRAWINGS

The patent or application file contains at least one drawing executed in color.

Copies of this patent or patent application publication with color drawing(s) will be provided by the Office upon request and payment of the necessary fee.

Example embodiments of the inventive concept will be more clearly understood from the following detailed description taken in conjunction with the accompanying drawings in which:

FIG. 1 is a graph showing the metronomic progress in CMOS transistor density and switching energy over time,

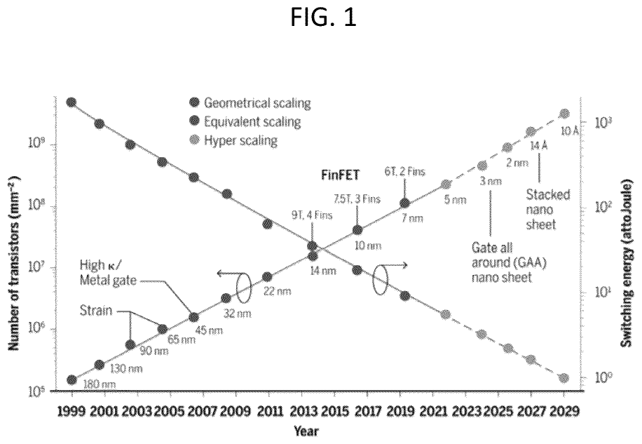

FIG. 2 shows a representative transistor structure,

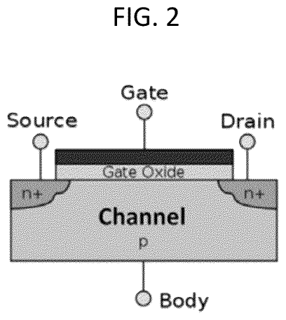

FIG. 3 is a graph showing the mobility (u) of electrons as a function of channel thickness (t_{CH}), and illustrates that for Si on insulators (SOI), the mobility degrades when t_{CH} is below 4 nm, while transition metal dichalcogenides (MoS₂, WSe₂, etc.) show robust mobility for thinner channels,

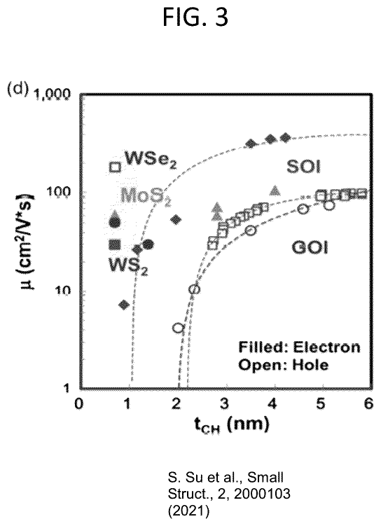

FIG. 4 is a schematic energy level diagram of surface charge transfer doping (SCTD) between organic molecules and MoS₂, and illustrates depletion and a p-doping process via SCTD of organic molecules with higher electron affinity (EA) than the ionization energy (IE) of TMDs,

FIG. 5 is a graph showing the computed mobility of MoS₂ with HfO₂ as a gate dielectric, in which the contribution from electron-phonon (E-Ph), surface optical phonon (SOP), charge impurities (CI), and the total effect are shown,

FIG. 6 is a diagram showing energy relative to vacuum for various compounds,

FIG. 7A is a graph showing the computed atom-projected electronic structure of WSe₂ on one layer of HfO₂,

FIG. 7B is a schematic diagram for p-doping TMDs by alloying HfO₂ with other transition metal oxides,

FIG. 7C is a graph showing the electronic structure of one case of Hf_{0.5}Ni_{0.5}O₂ where the conduction bands (CB) have a contribution from the Ni atoms that form lower CB than the pristine HfO₂ CB,

FIG. 8A shows one layer of NiO₂ being added to five layers of HfO₂ and interfaced with monolayer WSe₂, as well as Ni-doped HfO₂ clearly p-doping WSe₂,

FIG. 8B shows the dopant as being in a variable concentration in the oxide layer structure,

FIG. 9 is a graph showing proof of hardening of the softest optical mode on using a lighter metal atom using bulk cubic SnO₂ as an example, comparing the phonon bands to bulk cubic HfO₂, and

FIG. 10 is a graph showing a linear relationship between doping and dielectric constant.

### DETAILED DESCRIPTION OF EXAMPLE EMBODIMENTS

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

To further show the feasibility of TMDs as alternative channel material to Si, there is a need to be able to both n-dope and p-dope TMDs. TMDs like MoS₂ naturally form n-doped TMDs. However, strategies to p-dope TMDs have been largely unsuccessful.

Substitution doping of Nb or Ta of Mo has been proposed to p-dope MoS₂. However, higher concentration of dopants could make these layers metallic, leading to a short circuit. Further, by design, this approach creates more scattering centers in the channel layer which could affect the mobility of electrons. That is, p-doping may be achieved by creating defects or adding other transition metals directly into the TMD layer. This may act as scattering centers that may limit the electron mobility within a channel layer.

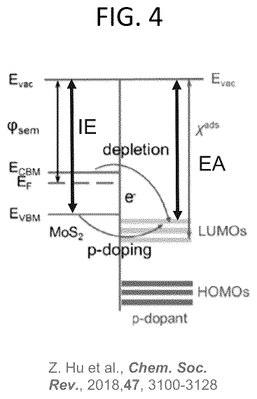

Another approach to p-dope TMDs is to use surface charge transfer doping (SCTD) between an organic molecule adsorbate and the TMD layer which naturally occurs for appropriate band alignment (see FIG. 4; the electron affinity, EA, of the organic layer is larger than the Ionization energy, IE, of TMDs). Unlike substitution doping, this approach does not degrade the crystal quality. However, adding organic molecules to transistors could lead to engineering challenges like thermal stability and scalability.

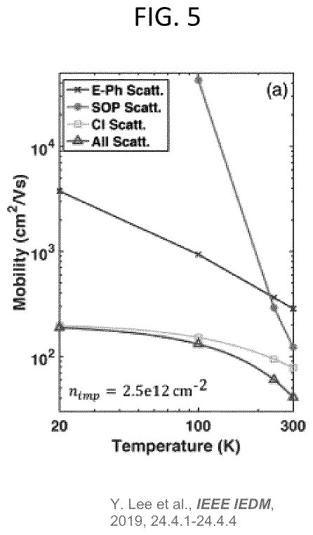

The inorganic gate oxide layer that is ever present in a transistor geometry could also lead to SCTD of TMDs. However, even in the clean limit (where charge impurity, CI, scattering is negligible) surface optical phonons (SOP) in the high-k layer can hinder the performance of the TMD layer at room temperature (see FIG. 5).

By appropriate doping of the high-k layer, the present disclosure could achieve p-doping of the nearby TMD layer while reducing the SOP that limits the mobility of the TMD layer.

The present disclosure resulted from screening the C2DB database for materials with a band gap >0.1 eV (semiconductors), electron affinity (EA Oxide)>ionization energy of MoSe₂ which has the lowest IE (5.03 eV); see Table 1 below, in which the ionization energy (IE) in eV is shown for different TMDs computed using PBE functional, and the corresponding comparisons with prior reports are also included. 42 candidate compounds with 25 unique elements were found.

TABLE 1

| Monolayer Ionization Energy | | |
|---|---|---|
| (eV) | PBE | Reported |
| MoS₂ | 5.98 | 5.77* |
| MoSe₂ | 5.03 | 5.34* |
| WS₂ | 5.75 | 5.72* |
| WSe₂ | 5.14 | 5.2* |
| h-BN | 5.57 | 6* |

*K. Keyshar et al., ACS Nano, 11, 8, 8223 (2017) + Y. Yang et al., Nano Lett. 20, 12, 8846 (2020)

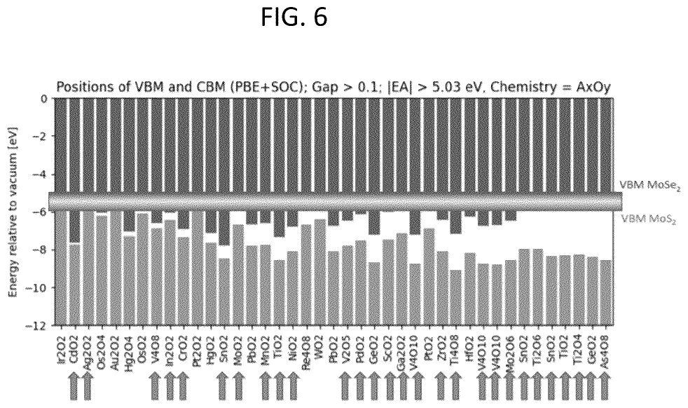

Next, atomic mass was used as a proxy for screening surface optical phonons (OPs). Of the 25 elements, 15 cations (blue arrows in the diagram shown in FIG. 6) were found to be lighter than Hf (178.5 a.m.u.). The bulk OP modes in these doped structure are believed to be harder than in HfO₂. This should alleviate the remote electron-phonon coupling mediated by the surface OPs of the oxide layer that limits the transport properties in the TMD layer.

The list of cations which can be used as p-dopants includes Cd, As, Cr, Pd, Sc, V, Sn, Mo, Mn, Ti, Ge, Ag, Ni, In, and Ga. As least one cation from the aforementioned list can be used in an embodiment of the present disclosure. In another embodiment, the list of cations includes Cr, V, Sn, Mo, Mn, Ti, Ge, Ag, Ni, In, and Ga, and in still another embodiment, the list of cations includes V, Sn, Mo, Mn, Ti, Ge, Ag, Ni, In, and Ga.

In the present disclosure, an oxide high-k gate dielectric layer is doped with a dopant from the above list of dopants. A standard oxide high-k gate dielectric layer can be used as the oxide high-k gate dielectric layer to be doped with a dopant. In this regard, the oxide for an oxide high-k gate dielectric layer in the present disclosure is one which has a dielectric constant higher than SiO₂, i.e., a dielectric constant higher than 3.9. As the oxide for the oxide high-k gate dielectric layer, binary and ternary oxides with their variations can be used in the present disclosure. In particular, at least one of binary and ternary oxides with their variations can be used in the present disclosure. HfO₂, ZrO₂, BaTiO₃, and doped-SrTiO₃ are examples of oxides which can be used. At least one of HfO₂, ZrO₂, BaTiO₃, and doped-SrTiO₃ can be used in the present disclosure.

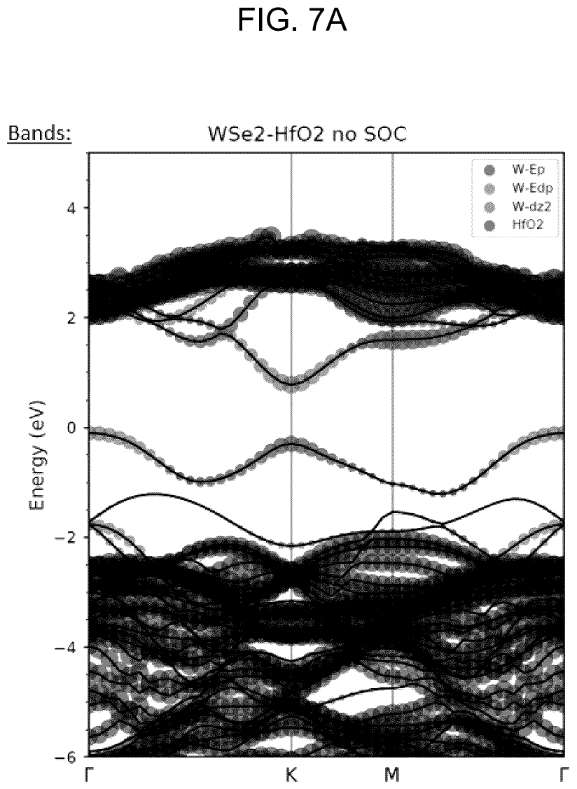

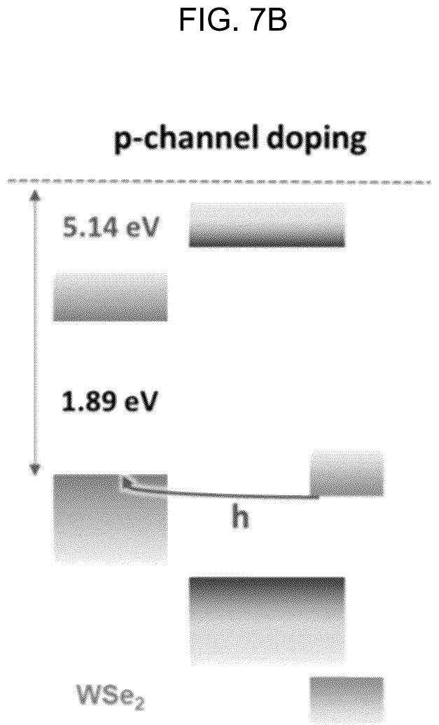

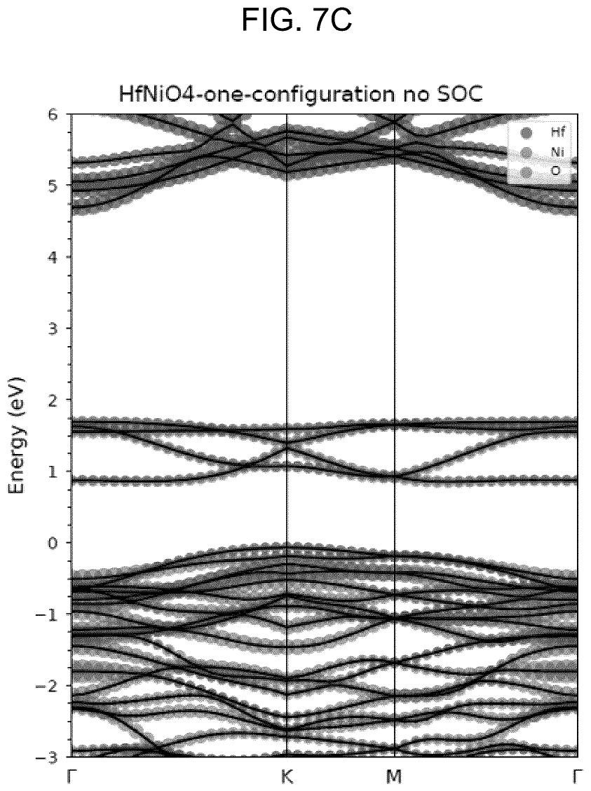

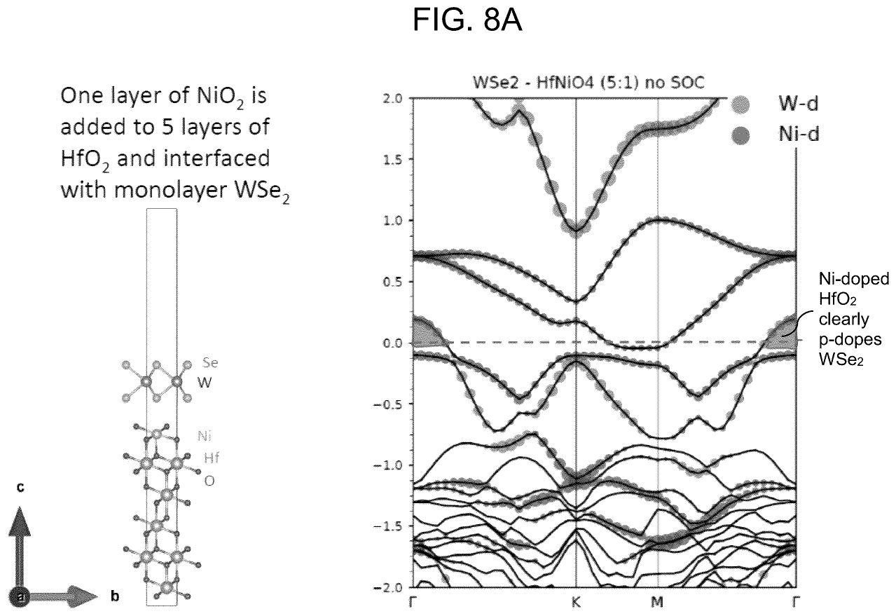

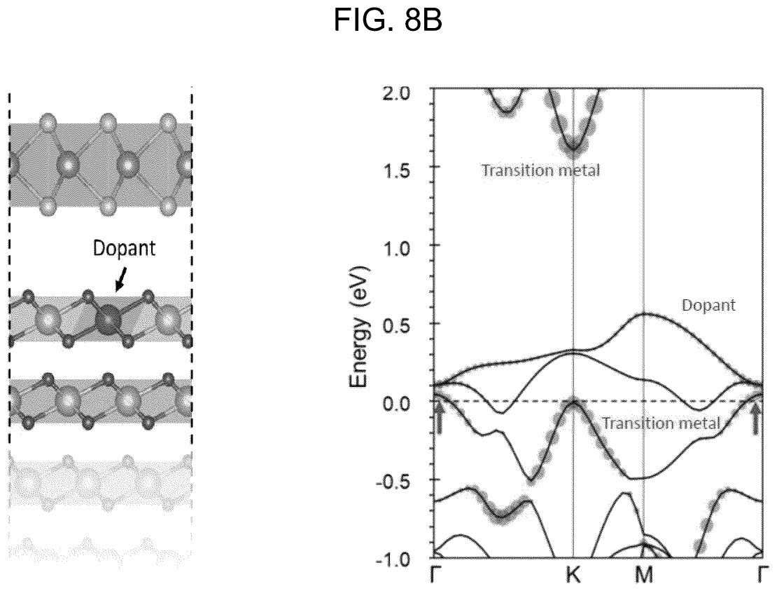

As noted above, HfO₂ is an example for the gate dielectric oxide in the present disclosure. HfO₂ is a well-studied high-k dielectric binary oxide. The band alignment of HfO₂ is not directly favorable for substrate p-doping TMDs—the conduction band minimum (CBM) of pristine HfO₂ is above the valence band maximum (VBM) of TMDs. The band alignment of Hf_{0.5}Ni_{0.5}O₂ is such that the CBM is made of Ni states, with a smaller band gap with the VBM having Hf contributions in addition to the dominant O states. This doped HfO₂ has the right band alignment relative to TMDs. See FIGS. 7A-7C, as well as FIG. 8.

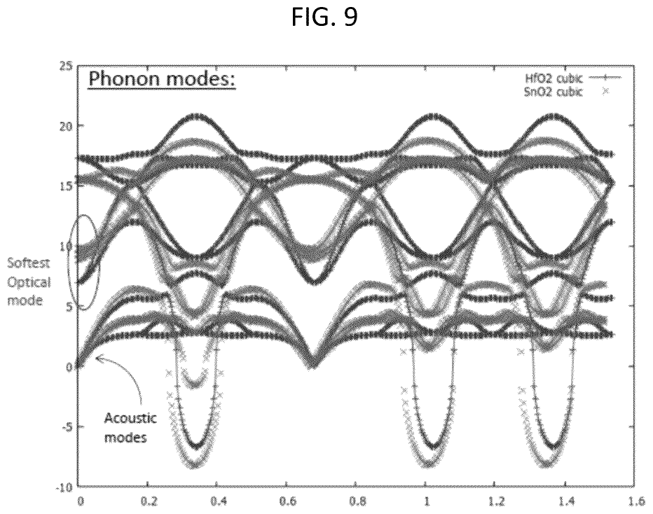

Further, proof of hardening of the softest optical mode on using a lighter metal atom using bulk cubic SnO₂ as an example is shown in FIG. 9, comparing the phonon bands to bulk cubic HfO₂.

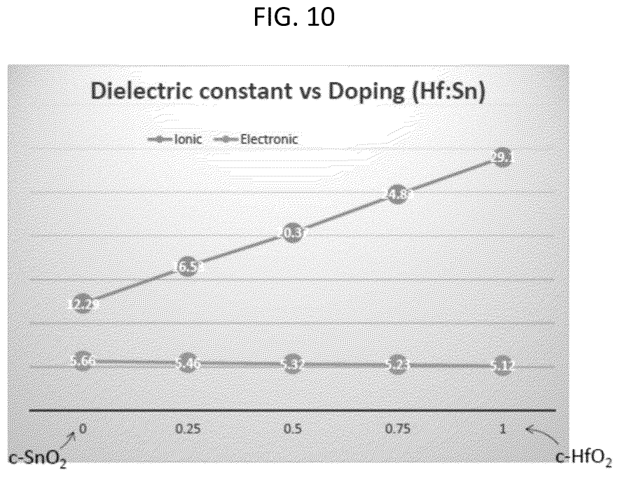

As shown in FIG. 10, a linear relationship is found between doping and dielectric constant. To maintain the high-k behavior of HfO₂ within a 25% limit, a doping concentration range of 0<x<0.25 is suggested. To maintain the high-k behavior of HfO₂ within a 20% limit, a doping concentration range of 0<x<0.2 is suggested.

Thus, one example embodiment provides a structure that includes p-doped thin layer that uses an oxide high-k gate dielectric (e.g., HfO₂) in an oxide layer doped with the chemistries Cd, As, Cr, Pd, Sc, V, Sn, Mo, Mn, Ti, Ge, Ag, Ni, In, or Ga within a fractional (x) limit 0<x<0.25 (or 0<x<0.2 in another embodiment), wherein the thin layer has a thickness of 10 nm or less (or, in another embodiment, 4 nm or less). The thin layer can be a monolayer, or it can comprise multiple layers. In some embodiments of the present disclosure, the thin layer can have a thickness of 0.6 nm or 0.8 nm, including a gap to the next layer. Another example embodiment provides a structure that includes p-doped transition metal dichalcogenides (TMDs) that use a binary oxide high-k gate dielectric (e.g., HfO₂) in an oxide layer doped with the chemistries Cd, As, Cr, Pd, Sc, V, Sn, Mo, Mn, Ti, Ge, Ag, Ni, In, or Ga within a fractional (x) limit 0<x<0.25, or 0<x<0.2 in another embodiment. Results show that the relative band alignment in conventional high-k oxides can be modified by the doping strategy disclosed herein. In one embodiment, this can include p-doping the neighboring TMD layer. Further, as disclosed herein, the optical phonons in the bulk can be stiffened, thereby suggesting the possibility of reducing surface optical phonon scattering. This should increase device performance. For doping in the range 0<x<0.25, the dielectric constant of the high-k layer is retained with 75% accuracy. For doping in the range 0<x<0.2, the dielectric constant of the high-k layer is retained with 80% accuracy.

TMDs which can be used in the structure include MoS₂, MoSe₂, WS₂, and WSe₂. At least one TMD can be used in an embodiment of the present disclosure. TMDs which can be used in the structure with some practical advantages include MoS₂ and WSe₂, but such does not limit the TMDs which can be used. A TMD which can be used in one example embodiment of the structure is WSe₂.

As noted above, a binary oxide high-k gate dielectric which can be used in the structure is, for example, HfO₂. ZrO₂, BaTiO₃, and doped-SrTiO₃ are all other examples of gate dielectric oxides that can be used, among the many gate dielectric oxides that can be used. HfO₂ has been used to demonstrate the doping in action in the present disclosure. However, the present disclosure should work with practically any oxide dielectrics as well. Thus, binary and ternary oxide with their variations are included in the present disclosure.

A preferred p-dopant which can be used in the structure is Ni, which was used to prove the doping in action. Other preferred dopants for p-doping TMDs include Sn, Ge, Mo, and Ti. As noted above, Cd, As, Cr, Pd, Sc, V, Sn, Mo, Mn, Ti, Ge, Ag, Ni, In, and Ga can be used as dopants in an embodiment of the present disclosure, or Cr, V, Sn, Mo, Mn, Ti, Ge, Ag, Ni, In, and Ga can be used as dopants in another embodiment, and V, Sn, Mo, Mn, Ti, Ge, Ag, Ni, In, and Ga can be used in yet another embodiment. 25 dopants which may be used in the present disclosure are set forth in FIG. 6.

Also, the present disclosure provides a method to p-dope a thin layer using a layer of an oxide high-k gate dielectric (e.g., HfO₂) by doping the oxide layer with Cd, As, Cr, Pd, Sc, V, Sn, Mo, Mn, Ti, Ge, Ag, Ni, In, or Ga within the fractional (x) limit 0<x<0.25 (or 0<x<0.2 in another embodiment), to thereby p-dope the thin layer by surface charge transfer doping, wherein the thin layer has a thickness of 10 nm or less (or, in another embodiment, 4 nm or less). As noted above, the thin layer can be a monolayer, or it can comprise multiple layers. In some embodiments of the present disclosure, the thin layer can have a thickness of 0.6 nm or 0.8 nm, including a gap to the next layer. Another example embodiment of the present disclosure provides a method to p-dope transition metal dichalcogenides (TMDs) using a binary oxide high-k gate dielectric (e.g., HfO₂) by doping the oxide layer with Cd, As, Cr, Pd, Sc, V, Sn, Mo, Mn, Ti, Ge, Ag, Ni, In, or Ga within the fractional (x) limit 0<x<0.25, or 0<x<0.2 in another embodiment, to thereby p-dope the transition metal dichalcogenide layer by surface charge transfer doping.

In particular, the present disclosure provides a method for p-doping a transition metal dichalcogenide layer comprising doping a binary oxide high-k gate dielectric layer with Cd, As, Cr, Pd, Sc, V, Sn, Mo, Mn, Ti, Ge, Ag, Ni, In, or Ga (or Cr, V, Sn, Mo, Mn, Ti, Ge, Ag, Ni, In, or Ga in another embodiment, or V, Sn, Mo, Mn, Ti, Ge, Ag, Ni, In, or Ga in yet another embodiment) within a fractional (x) limit 0<x<0.25, or 0<x<0.2 in another embodiment, to thereby p-dope the transition metal dichalcogenide layer by surface charge transfer doping.

TMDs which can be used in the method include MoS₂, MoSe₂, WS₂, and WSe₂. TMDs which can be used in the method with some practical advantages include MoS₂ and WSe₂, but such does not limit the TMDs which can be used. A TMD which can be used in one example embodiment of the method is WSe₂.

A binary oxide high-k gate dielectric which can be used in the method is, for example, HfO₂. ZrO₂, BaTiO₃, and doped-SrTiO₃ are all other examples of gate dielectric oxides that can be used, among the many gate dielectric oxides that can be used. As noted above, HfO₂ has been used to demonstrate the doping in action in the present disclosure. However, the present disclosure should work with practically any oxide dielectrics as well. Thus, binary and ternary oxide with their variations are included in the present disclosure.

A preferred p-dopant which can be used in the method is Ni, which was used to prove the doping in action. Other preferred dopants for p-doping TMDs include Sn, Ge, Mo, and Ti. As noted above, Cd, As, Cr, Pd, Sc, V, Sn, Mo, Mn, Ti, Ge, Ag, Ni, In, and Ga can be used as dopants in an embodiment of the present disclosure, or Cr, V, Sn, Mo, Mn, Ti, Ge, Ag, Ni, In, and Ga can be used as dopants in another embodiment, and V, Sn, Mo, Mn, Ti, Ge, Ag, Ni, In, and Ga can be used in yet another embodiment. 25 dopants which may be used in the present disclosure are set forth in FIG. 6 . . .

The present disclosure allows to p-dope TMDs using the existing geometry of gate dielectrics without degrading the device performance by reducing scattering mechanisms while retaining the high-dielectric behavior.

In particular, cation doping of HfO₂ with transition metals whose oxides have an ionization energy larger than the electron affinity of TMD is provided.

By filtering for lighter transition metal dopants (in the case of HfO₂, lighter than Hf), the surface optical phonon modes in HfO₂ are considered to be weakened as well, thereby improving the transport properties of the TMD layer.

As long as the doping concentration is small (<25%, or <20% in another embodiment), the high-k dielectric properties present in HfO₂ are considered to remain within the 25% limit, or within the 20% limit in another embodiment.

The present disclosure is agnostic to the way the dopant is introduced into the gate oxide. Therefore, the results of the present disclosure are considered to be qualitatively true for delta-doped gate-oxide (see, e.g., Y. Kozuka et al, Enhancing the electron mobility via delta-doping in SrTiO₃, Appl. Phys. Lett., 97, 222115 (2010)), and for point doping into crystalline gate-oxide (see, e.g., W. Beall Fowler, Point Defects, Reference Module in Materials Science and Materials Engineering, Elsevier, 2022), and even for an amorphous phase of gate-dielectric layer with these dopant atoms (Theresia Knobloch et al, Improving stability in two-dimensional transistors with amorphous gate oxides by Fermi-level tuning, Nature Electronics, 5, 356-366 (2022)). As long as the dopant atoms are in the right oxidation state and are close to the interface allowing for charge transfer between the dopant sublayer and the TMD layer, it is believed that the doping will be robust.

The present disclosure identifies oxide-based dopants to dope the gate-dielectric layer, and it is compatible with all the existing transistor geometries where the gate dielectric layer is next to the channel layer. This includes the planar MOSFET, Fin-FET and hyperscaler gate-all-around structure geometries (see, e.g., Brian Bailey, What Designers Need To Know About GAA, Semiconductor Engineering (2023)).

Advantages of the present disclosure include no need for substitution doping of TMDs to p-dope. Substitution doping can degrade the device performance as it is creating more defects within the channel. The approach of the present disclosure is a non-invasive approach for doping the channel. Further, the good features (large dielectric values) of having a high-k dielectric are retained within the fractional doping specified in the present disclosure, while the negative attributes (scattering via surface phonons) are also potentially mitigated.

Using elements with lower atomic mass than Hf when HfO₂ is used as the gate dielectric is also advantageous apart from the above-discussed reduction of surface optical phonon scattering. This choice of elements with lighter atomic mass compared to the gate oxide cation has two advantages. Firstly, a lower atomic mass can act as a proxy for harder surface optical phonons within a harmonic approximation. Surface optical phonons in the surrounding gate dielectric are a dominant source of channel carrier scatter at room temperature even in the clean limit where charged impurity scattering is negligible. Doping gate oxides with elements with lower atomic mass can reduce this surface optical phonon scattering by hardening these optical phonons. Secondly, doping HfO₂ with lighter atoms stabilizes the high-k tetragonal phase (see C. K. Lee et al., First-principles study on doping and phase stability of HfO₂, Physical Review B, 78 012102, 2008). This is extremely advantageous as the tetragonal phase HfO₂ is reported to have the largest dielectric constant (k ˜226.2) compared to the other phases. Further, at room temperature HfO₂ forms in monoclinic phase with a relatively low dielectric constant (k ˜20.2). The tetragonal phase is only stable in a thermal window above 2000 K and below 2900 K. As lighter dopant atoms in HfO₂ stabilize the high-k tetragonal phase relative to the monoclinic phase, this can lead to more efficient equivalent oxide scaling with the same physical oxide thickness. Consequently, dopants with lower atomic mass can not only reduce the scattering of carriers from surface optical phonons in the gate dielectric but also enhance the dielectric behavior of the gate dielectrics like HfO₂.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A structure comprising a p-doped thin layer and an oxide high-k gate dielectric layer doped with Cd, As, Cr, Pd, Sc, V, Sn, Mo, Mn, Ti, Ge, Ag, Ni, In, or Ga within a fractional (x) limit 0<x<0.25, wherein the thin layer has a thickness of 10 nm or less.

2. A structure comprising a p-doped transition metal dichalcogenide layer and a binary oxide high-k gate dielectric layer doped with Cr, V, Sn, Mo, Mn, Ti, Ge, Ag, Ni, In, or Ga within a fractional (x) limit 0<x<0.2.

3. The structure according to claim 1, wherein the thin layer is a transition metal dichalcogenide layer.

4. The structure according to claim 3, wherein the transition metal dichalcogenide layer comprises a transition metal dichalcogenide selected from MoS₂, MoSe₂, WS₂, and WSe₂.

5. The structure according to claim 4, wherein the transition metal dichalcogenide is selected from MoS₂ and WSe₂.

6. The structure according to claim 1, wherein the oxide high-k gate dielectric layer comprises HfO₂, ZrO₂, BaTiO₃, or doped-SrTiO₃.

7. The structure according to claim 6, wherein the oxide high-k gate dielectric layer comprises HfO₂.

8. The structure according to claim 1, wherein the oxide high-k gate dielectric layer is doped with Sn, Mo, Ti, Ge, or Ni.

9. The structure according to claim 8, wherein the oxide high-k gate dielectric layer is doped with Ni.

10. The structure according to claim 2, wherein the p-doped transition metal dichalcogenide layer comprises a transition metal dichalcogenide selected from MoS₂ and WSe₂, the oxide high-k gate dielectric layer comprises HfO₂, and the oxide high-k gate dielectric layer is doped with Ni.

11. A method for p-doping a thin layer comprising doping an oxide high-k gate dielectric layer with Cd, As, Cr, Pd, Sc, V, Sn, Mo, Mn, Ti, Ge, Ag, Ni, In, or Ga within a fractional (x) limit 0<x<0.25 to thereby p-dope the thin layer by surface charge transfer doping and form a structure according to claim 1, wherein the thin layer has a thickness of 10 nm or less.

12. A method for p-doping a transition metal dichalcogenide layer comprising doping a binary oxide high-k gate dielectric layer with V, Sn, Mo, Mn, Ti, Ge, Ag, Ni, In, or Ga within a fractional (x) limit 0<x<0.2 to thereby p-dope the transition metal dichalcogenide layer by surface charge transfer doping and form a structure according to claim 2.

13. The method according to claim 11, wherein the thin layer is a transition metal dichalcogenide layer.

14. The method according to claim 13, wherein the transition metal dichalcogenide layer comprises a transition metal dichalcogenide selected from MoS₂, MoSe₂, WS₂, and WSe₂.

15. The method according to claim 14, wherein the transition metal dichalcogenide is selected from MoS₂ and WSe₂.

16. The method according to claim 11, wherein the oxide high-k gate dielectric layer comprises HfO₂, ZrO₂, BaTiO₃, or doped-SrTiO₃.

17. The method according to claim 16, wherein the oxide high-k gate dielectric layer comprises HfO₂.

18. The method according to claim 11, wherein the oxide high-k gate dielectric layer is doped with Sn, Mo, Ti, Ge, or Ni.

19. The method according to claim 18, wherein the oxide high-k gate dielectric layer is doped with Ni.

20. The method according to claim 12, wherein the p-doped transition metal dichalcogenide layer comprises a transition metal dichalcogenide selected from MoS₂ and WSe₂, the oxide high-k gate dielectric layer comprises HfO₂, and the oxide high-k gate dielectric layer is doped with Ni.
